(19) United States
(12) Patent Application Publication
(10) Pub. No.: US 2026/0323821 A1
(43) Pub. Date: Oct. 15, 2026

(54) MULTILAYER WIRING SUBSTRATE AND METHOD FOR MANUFACTURING THE SAME

(71) Applicant: Japan Display Inc., Tokyo (JP)

(72) Inventors: Toshiki KANEKO, Tokyo (JP); Ryoichi MATSUMOTO, Tokyo (JP); Yoshikatsu IMAZEKI, Tokyo (JP)

(73) Assignee: Japan Display Inc., Tokyo (JP)

(21) Appl. No.: 19/691,646

(22) Filed: May 29, 2026

Related U.S. Application Data
(63) Continuation of application No. PCT/JP2024/041231, filed on Nov. 21, 2024.

(30) Foreign Application Priority Data
Dec. 18, 2023 (JP) 2023-213080

(51) Int. Cl. H05K 1/03; H05K 1/11; H05K 3/46

(52) U.S. Cl. CPC H05K 1/036; H05K 1/115; H05K 3/4644

(57) ABSTRACT

A multilayer wiring substrate includes a first resin layer; a second resin layer overlapping the first resin layer in a plan view; at least one intermediate resin layer between the first resin layer and the second resin layer; and at least one conductive via provided in the at least one intermediate resin layer. The first resin layer forms an outermost layer on a first surface side, the second resin layer forms an outermost layer on a second surface side opposite to the first surface side, and a Young's modulus of the first resin layer and a Young's modulus of the second resin layer are higher than a Young's modulus of the at least one intermediate resin layer.

### CROSS-REFERENCE TO RELATED APPLICATIONS

This application is a Continuation of International Patent Application No. PCT/JP2024/041231, filed on Nov. 21, 2024, which claims the benefit of priority to Japanese Patent Application No. 2023-213080, filed on Dec. 18, 2023, the entire contents of each are incorporated herein by reference.

### FIELD

An embodiment of the present invention relates to a structure of a multilayer wiring substrate for establishing electrical connection between circuits on front and back surfaces and relaying between the circuits, and a method for manufacturing the multilayer wiring substrate.

### BACKGROUND

When electrically connecting a semiconductor element manufactured in a wafer process and a printed wiring substrate, an intermediate substrate for pitch conversion called an interposer (also referred to as a multilayer wiring substrate or an interposer) is used. For example, an interposer (glass interposer) in which a plurality of wiring layers and a plurality of micro-bumps are formed on a glass substrate is disclosed (for example, International Patent Publication No. WO2001/082666). Also disclosed is an interposer having a first core in which a first through electrode is formed, a second core in which a second through electrode is formed, and wiring that connects the first through electrode and the second through electrode, wherein the first core and the second core are laminated (for example, Japanese Patent Laid-Open Patent Publication No. 2017-130571).

As a method for manufacturing an interposer, there is a manufacturing method in which an interlayer insulating layer and a conductive via are formed on a silicon wafer to form a multilayer structure. Further, instead of a silicon interposer, there is a method in which a redistribution layer of a resin substrate is used as an interposer (RDL interposer).

### SUMMARY

A multilayer wiring substrate according to an embodiment of the present invention includes a first resin layer; a second resin layer overlapping the first resin layer in a plan view; at least one intermediate resin layer between the first resin layer and the second resin layer; and at least one conductive via provided in the at least one intermediate resin layer. The first resin layer forms an outermost layer on a first surface side, the second resin layer forms an outermost layer on a second surface side opposite to the first surface side, and a Young's modulus of the first resin layer and a Young's modulus of the second resin layer are higher than a Young's modulus of the at least one intermediate resin layer.

A method for manufacturing a multilayer wiring substrate according to an embodiment of the present invention having a first resin layer, a second resin layer overlapping the first resin layer in a plan view, at least one intermediate resin layer between the first resin layer and the second resin layer, and at least one conductive via provided in the at least one intermediate resin layer, the method includes forming the first resin layer by applying a non-photosensitive resin composition onto a glass substrate and curing the non-photosensitive resin composition; forming the second resin layer from a thermosetting organic-inorganic composite material; and forming the at least one intermediate resin layer from a photosensitive resin material.

A multilayer wiring substrate according to an embodiment of the present invention includes a first resin layer formed of a non-photosensitive material or a photosensitive resin material; a second resin layer overlapping the first resin layer in a plan view and formed of a thermosetting organic-inorganic composite material; at least one intermediate resin layer formed of a photosensitive material between the first resin layer and the second resin layer; and at least one conductive via provided in the at least one intermediate resin layer. The first resin layer forms an outermost layer on a first surface side, and the second resin layer forms an outermost layer on a second surface side opposite to the first surface side.

### BRIEF DESCRIPTION OF DRAWINGS

FIG. 1 is a cross-sectional view of a multilayer wiring substrate according to an embodiment of the present invention.

FIG. 2 is a cross-sectional view of a multilayer wiring substrate according to an embodiment of the present invention.

FIG. 3A is a cross-sectional view illustrating a method for manufacturing a multilayer wiring substrate according to an embodiment of the present invention.

FIG. 3B is a cross-sectional view illustrating a method for manufacturing a multilayer wiring substrate according to an embodiment of the present invention.

FIG. 3C is a cross-sectional view illustrating a method for manufacturing a multilayer wiring substrate according to an embodiment of the present invention.

FIG. 3D is a cross-sectional view illustrating a method for manufacturing a multilayer wiring substrate according to an embodiment of the present invention.

FIG. 3E is a cross-sectional view illustrating a method for manufacturing a multilayer wiring substrate according to an embodiment of the present invention.

FIG. 3F is a cross-sectional view illustrating a method for manufacturing a multilayer wiring substrate according to an embodiment of the present invention.

FIG. 4 is a cross-sectional view illustrating a method for manufacturing a multilayer wiring substrate according to an embodiment of the present invention.

FIG. 5 is a cross-sectional view of a multilayer wiring substrate according to an embodiment of the present invention.

FIG. 6 is a cross-sectional view of a multilayer wiring substrate according to an embodiment of the present invention.

FIG. 7 is a cross-sectional view of a multilayer wiring substrate according to an embodiment of the present invention.

FIG. 8 is a cross-sectional view of a multilayer wiring substrate according to an embodiment of the present invention.

FIG. 9 is a cross-sectional view of a multilayer wiring substrate according to an embodiment of the present invention.

FIG. 10A is a cross-sectional view illustrating a method for manufacturing a multilayer wiring substrate according to an embodiment of the present invention.

FIG. 10B is a cross-sectional view illustrating a method for manufacturing a multilayer wiring substrate according to an embodiment of the present invention.

### DESCRIPTION OF EMBODIMENTS

Hereinafter, embodiments of the present invention will be described with reference to the drawings and the like. However, the present invention can be implemented in many different modes and should not be interpreted as being limited to the description of the embodiments described below. For clarity of explanation, the drawings may schematically represent the width, thickness, shape, and the like of each part compared to actual aspects, but these are merely examples and do not limit the interpretation of the present invention. In addition, in this specification and each drawing, elements similar to those described above with respect to previous drawings are denoted by the same reference signs (or reference signs with A, B, or the like added after numbers), and detailed description thereof may be omitted as appropriate. Furthermore, labels such as “first” and “second” added to each element are convenient labels used to distinguish each element and have no further meaning unless otherwise specified.

In the present specification, when a member or a region is said to be “on (or under)” another member or region, this includes not only a case where the member or region is directly on (or directly under) the other member or region but also a case where the member or region is above (or below) the other member or region, unless otherwise specifically limited. That is, a case where another component is included between the member or region and the other member or region above (or below) the other member or region is also included.

### First Embodiment

This embodiment shows a configuration of a multilayer wiring substrate having an intermediate resin layer formed using a photosensitive material between a first resin layer and a second resin layer each formed using a non-photosensitive resin material. The multilayer wiring substrate shown in this embodiment is a redistribution substrate that connects an integrated circuit (or circuit board) on an upper-layer side and an integrated circuit (or circuit board) on a lower-layer side, and is a wiring substrate also referred to as an RDL (Redistribution Layer) interposer.

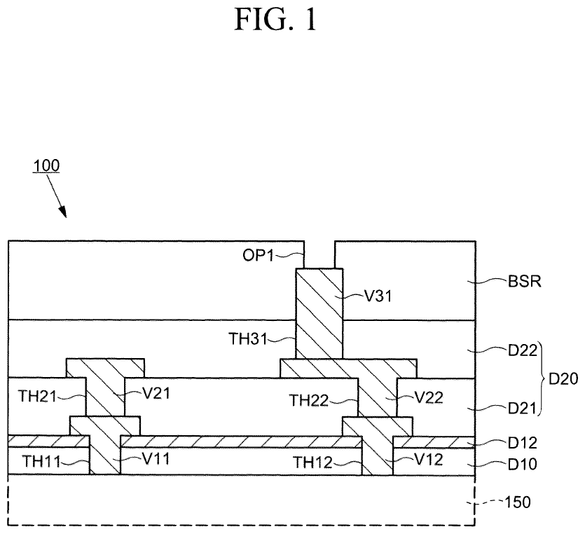

FIG. 1 is a cross-sectional view illustrating a multilayer wiring substrate 100 according to an embodiment of the present invention. The multilayer wiring substrate 100 includes a first resin layer D10, a second resin layer BSR, at least one intermediate resin layer D20 sandwiched between the first resin layer D10 and the second resin layer BSR, and at least one conductive via.

Note that, in this embodiment, the intermediate resin layer D20 refers to a layer provided between the first resin layer D10 and the second resin layer BSR, and there is no limitation on the number of layers to be stacked. Further, conductive vias and wiring are appropriately provided in the intermediate resin layer D20. FIG. 1 shows an example in which the at least one intermediate resin layer D20 is composed of a first intermediate resin layer D21 and a second intermediate resin layer D22, first conductive vias V11 and V12 are provided in the first resin layer D10, second conductive vias V21 and V22 are provided in the first intermediate resin layer D21, and a third conductive via V31 is provided in the second intermediate resin layer D22.

The second resin layer BSR is arranged so as to overlap the first resin layer D10 in a plan view. The first resin layer D10 is an outermost layer on one surface (first surface) side of the multilayer wiring substrate 100, and the second resin layer BSR is an outermost layer on the other surface (second surface (a surface opposite to the first surface)) side. The first intermediate resin layer D21 and the second intermediate resin layer D22 are arranged so as to be sandwiched between the first resin layer D10 and the second resin layer BSR. The number of layers of the intermediate resin layer D20 is not limited to two, and may be one, or may have a structure in which three or more layers are stacked.

The first conductive vias V11 and V12 are conductive members provided in the first via holes TH11 and TH12 penetrating the first resin layer D10. The second conductive vias V21 and V22 are conductive members provided in the second via holes TH21 and TH22 penetrating the first intermediate resin layer D21, and the third conductive via V31 is a conductive member provided so as to penetrate the second intermediate resin layer D22 and protrude into the second resin layer BSR. The first conductive vias V11 and V12, the second conductive vias V21 and V22, and the third conductive via V31 are formed of a metallic material and are provided so as to fill the respective via holes.

Each conductive via may be arranged so as to form an electrical connection with an upper-layer-side or lower-layer-side via. For example, as shown in FIG. 1, second conductive vias V21 and V22 may be arranged to be respectively connected on the first conductive vias V11 and V12, and a third conductive via V31 may be arranged to be connected on the second conductive via V22. Further, although not shown in FIG. 1, wiring for forming redistribution may be appropriately connected to each via. The wiring is formed of the same conductive layer as a conductive layer forming each via.

The multilayer wiring substrate 100 is formed on the glass substrate 150, and after each layer is formed, is separated from the glass substrate 150. As the glass substrate 150, it is preferable to use an alkali-free glass substrate. For the glass substrate 150, application of a large-area glass substrate (mother glass substrate) such as those used in the manufacture of liquid crystal displays is also possible. By using such a large-area glass substrate, a plurality of multilayer wiring substrates 100 can be built in one glass substrate, and productivity can be increased by singulation at a final stage of the process.

Note that, although the glass substrate 150 is exemplified in this embodiment, a substrate applicable to the manufacture of the multilayer wiring substrate 100 is not limited to the glass substrate, and a semiconductor substrate such as a silicon wafer, a ceramic substrate, a quartz substrate, or the like can be applied.

After the multilayer wiring substrate 100 is separated from the glass substrate 150, the first conductive vias V11 and V12 are exposed on an outer surface on the side of the first resin layer D10. On the other hand, the third conductive via V31 is in a state of being covered with the second resin layer BSR, but a structure exposed to the outside is formed by providing the first opening OP1.

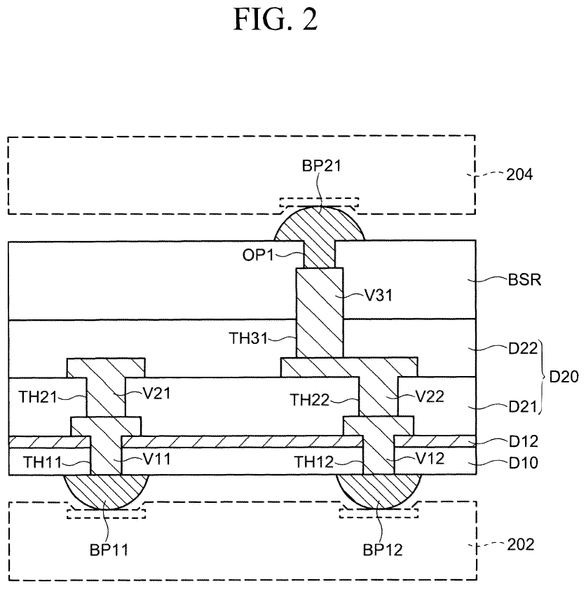

FIG. 2 shows a structure in which first bumps BP11 and BP12 electrically connected to the first conductive vias V11 and V12 are provided on the side of the first resin layer D10, and a second bump BP21 electrically connected to the third conductive via V31 is provided on the side of the second resin layer BSR. The first bumps BP11 and BP12 are provided to form an electrical connection with the first integrated circuit (or first circuit board) 202, and the second bump BP21 is provided to form an electrical connection with the second integrated circuit (or second circuit board) 204. The first bumps BP11 and BP12 and the second bump BP21 can be formed using a metallic material such as solder, gold (Au), or copper (Cu).

Referring back to FIG. 1, the first resin layer D10, the second resin layer BSR, and the intermediate resin layer D20 (the first intermediate resin layer D21 and the second intermediate resin layer D22) are layers formed of a resin material. The first resin layer D10 and the second resin layer BSR are formed of a material having a higher Young's modulus than that of the intermediate resin layer D20 (the first intermediate resin layer D21 and the second intermediate resin layer D22). For example, the Young's modulus of the first resin layer D10 and the Young's modulus of the second resin layer BSR are 5 GPa or more, preferably 7 GPa or more. On the other hand, the Young's modulus of the intermediate resin layer D20 (the first intermediate resin layer D21 and the second intermediate resin layer D22) may be less than 5 GPa.

Because the first resin layer D10 and the second resin layer BSR have such Young's moduli, the rigidity of the multilayer wiring substrate 100 can be increased, and flatness can be ensured. The resin layer is formed by applying a composition containing a precursor of a predetermined resin material (hereinafter also referred to as a “resin composition”) onto a substrate and curing the composition. Resin compositions are roughly classified into photocurable resin compositions and thermosetting resin compositions. Among these, in order to obtain a high Young's modulus, it is preferable to use a thermosetting resin composition that does not include a photosensitive group.

Therefore, the first resin layer D10 is preferably formed using a non-photosensitive resin composition. In other words, it is preferable that the first resin layer D10 is formed of a thermosetting resin composition. For example, the first resin layer D10 can be formed of non-photosensitive (thermosetting) polyimide. Such a first resin layer D10 is a resin layer that includes an imide ring bond and does not include a photosensitive group. Since the first resin layer D10 does not include a photosensitive group, the Young's modulus can be increased. That is, a resin layer formed of non-photosensitive polyimide can have, for example, a Young's modulus of 7 GPa or more, for example, a Young's modulus of 7.7 GPa. Note that, although the Young's modulus changes depending on manufacturing conditions (such as a curing temperature) of the non-photosensitive polyimide resin composition, in this embodiment, it is sufficient if the Young's modulus is 5 GPa or more, preferably 7 GPa or more.

The first resin layer D10 formed of a non-photosensitive resin composition (thermosetting resin composition) has internal stress, and the internal stress is tensile stress. For example, in a case where the first resin layer D10 is formed of a non-photosensitive polyimide resin composition, the tensile stress is about 20 MPa. When the first resin layer D10 has tensile stress, the glass substrate 150 is caused to warp during manufacture, and the multilayer wiring substrate 100 is caused to warp after manufacture (after being separated from the glass substrate 150).

Therefore, as shown in FIG. 1, it is preferable to provide a first inorganic insulating layer D12 having compressive stress on the first resin layer D10. That is, by providing the first inorganic insulating layer D12 having compressive stress, the tensile stress of the first resin layer D10 can be offset, and warping of the glass substrate 150 during manufacture and warping of the multilayer wiring substrate 100 after manufacture can be prevented.

As the first inorganic insulating layer D12, for example, a silicon nitride layer is used. The silicon nitride layer can be formed by a vapor deposition method (plasma CVD method), and by controlling film formation conditions, compressive stress can remain. For example, by increasing a film density of the silicon nitride layer, the silicon nitride layer can have compressive stress

First via holes TH11 and TH12 are provided in the first resin layer D10. In a case where the first resin layer D10 is formed using a non-photosensitive resin composition, in order to form the first via holes TH11 and TH12, it is necessary to produce a mask by photolithography and form openings by etching. In a case where the first inorganic insulating layer D12 is provided, it is necessary to form openings also in this layer. In a case where the first inorganic insulating layer D12 is formed of a silicon nitride layer, the openings can be formed relatively easily by dry etching using a fluorine-based etching gas. After that, for subsequent etching of the first resin layer D10, the first inorganic insulating layer D12 can be used as a hard mask. Since the hard mask has higher etching resistance than a mask formed of a resist material, sidewalls of the first via holes TH11 and TH12 can be formed substantially vertical.

Similar to the first resin layer D10, a thermosetting resin material is used for the second resin layer BSR. The second resin layer BSR can be formed using an organic-inorganic hybrid material composed of an organic material and an inorganic material. For example, the second resin layer BSR can be formed using a coating-type thermosetting epoxy resin composition containing an epoxy resin, an active ester compound including a naphthalene structure, and an inorganic filler.

The second resin layer BSR may be provided as a film-like or sheet-like intermediate material called a prepreg (a prepreg containing no glass fiber) formed of the thermosetting epoxy resin material as described above, and may be formed by being bonded onto the intermediate resin layer D20 and thermally cured. Alternatively, the second resin layer BSR may be formed by applying the thermosetting epoxy resin composition as described above onto the intermediate resin layer D20 and thermosetting the composition. Since the second resin layer BSR is formed of such a material, the second resin layer BSR is formed to be thicker than the first resin layer D10.

When formed using such a thermosetting resin material, the second resin layer BSR can have a Young's modulus of 7 to 13 GPa.

The intermediate resin layer D20 (the first intermediate resin layer D21 and the second intermediate resin layer D22) is formed of a photosensitive resin material. As the photosensitive resin material, a phenolic or polyimide resin material can be used. The intermediate resin layer D20 (the first intermediate resin layer D21 and the second intermediate resin layer D22) can be formed by applying a resin composition including a precursor of the photosensitive resin material as described above and a photosensitive group, and performing exposure, development, and curing. As the photosensitive resin composition, both a positive-type composition (in which an exposed portion has increased solubility in a developer and is removed, while an unexposed portion remains) and a negative-type composition (in which an exposed portion has decreased solubility in a developer and remains, while an unexposed portion is removed) can be applied.

The second via holes TH21 and TH22 are simultaneously formed in a process of exposing and developing the first intermediate resin layer D21, and the third via hole TH31 is simultaneously formed in a process of exposing and developing the second intermediate resin layer D22. For example, in a case where a positive-type resin composition is used, the respective via holes can be formed by performing exposure using a photomask that exposes portions for the second via holes TH21 and TH22 and the third via hole TH31, and performing development.

The first conductive vias V11 and V12, the second conductive vias V21 and V22, and the third conductive via V31 are formed of a conductive material such as copper (Cu), tungsten (W), or polysilicon. Among these, copper (Cu) is a preferable material from the standpoint of reducing the resistance of the vias. Such conductive vias are formed by, for example, an electroplating method. Although details of the manufacturing process will be described later, by forming a seed layer by a sputtering method, subsequently forming a mask pattern using a resist, and forming a plating layer by electroplating (a semi-additive method), the first conductive vias V11 and V12, the second conductive vias V21 and V22, and the third conductive via V31 can be formed so as to fill the via holes in the corresponding regions.

Since the Young's moduli of the first resin layer D10 and the second resin layer BSR located at the outermost layers is higher than that of the intermediate resin layer D20 formed of a photosensitive material, the multilayer wiring substrate 100 according to this embodiment can prevent warping, has excellent flatness when viewed as a whole, and can also increase flatness when viewed microscopically (when viewed in terms of a size of components to be mounted). Thereby, mounting accuracy of semiconductor integrated circuits (or circuit boards) mounted on an upper side and a lower side of the multilayer wiring substrate 100 can be increased.

Next, a method for manufacturing the multilayer wiring substrate 100 shown in FIG. 1 will be described. Here, an example is shown in which the first resin layer D10 and the second resin layer BSR are formed using a non-photosensitive resin material, the intermediate resin layer D20 is formed using a photosensitive resin material, and the first conductive vias V11 and V12, the second conductive vias V21 and V22, and the third conductive via V31 are formed by a semi-additive method.

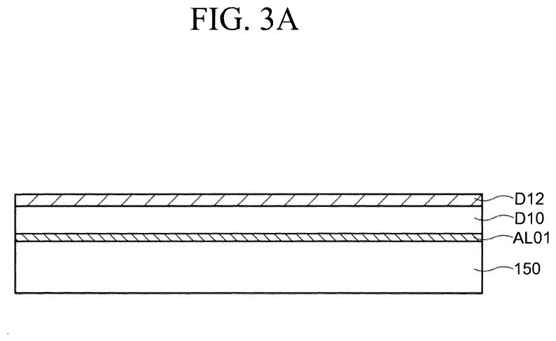

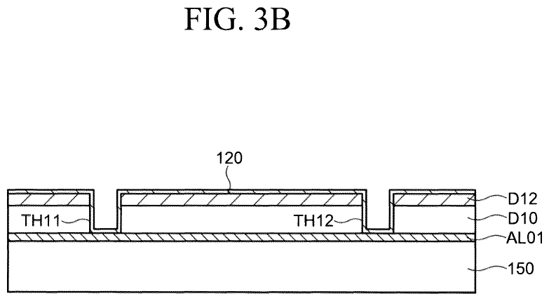

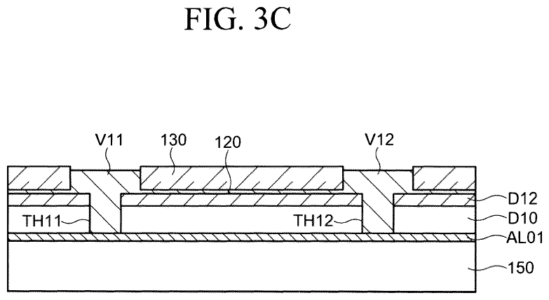

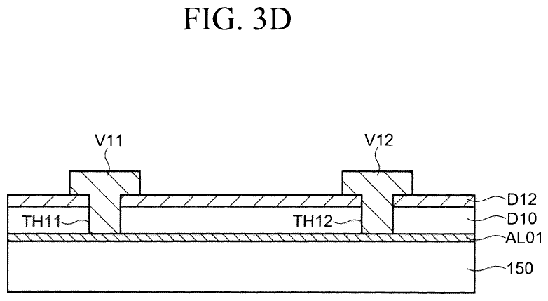

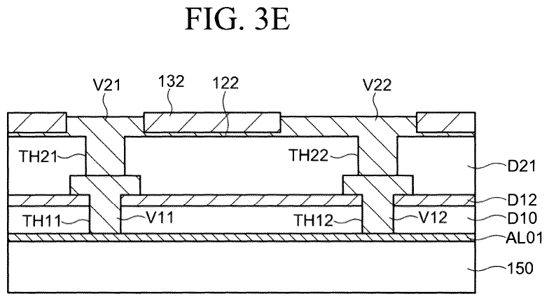

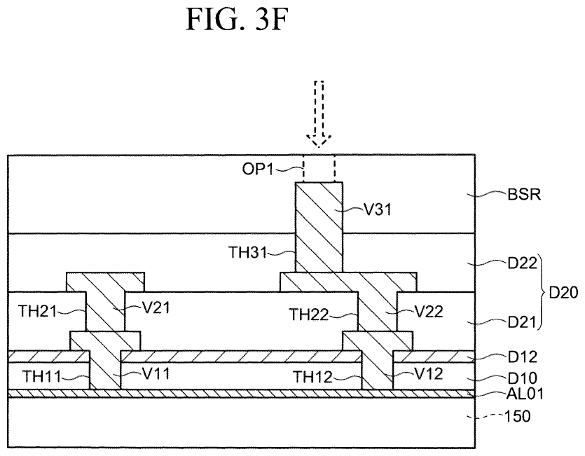

FIG. 3A shows a step of forming a sacrificial layer AL01 on a glass substrate 150, and forming a first resin layer D10 and a first inorganic insulating layer D12 thereon. The sacrificial layer AL01 is provided to separate the multilayer wiring substrate 100 from the glass substrate 150 after the multilayer wiring substrate 100 is formed on the glass substrate 150. The sacrificial layer AL01 is formed of, for example, a hydrogenated amorphous silicon film. Hydrogenated amorphous silicon can be formed by a vapor deposition method (plasma CVD method) using silane (SiH₄) and hydrogen (H₂) gases. Note that, if separation is possible without using the sacrificial layer AL01 depending on patterning, the sacrificial layer AL01 can be omitted.

Further, the sacrificial layer AL01 may be formed of a resin material. For example, the sacrificial layer AL01 may be formed by applying a polyimide varnish including a soluble polyimide resin, a thermosetting cross-linking agent, and a solvent, and performing heat treatment at a temperature lower than a cross-linking start temperature of the cross-linking agent.

The first resin layer D10 is formed of a thermosetting (non-photosensitive) polyimide material with a thickness of 3 μm to 10 μm, for example, 5 μm. Specifically, the first resin layer D10 is formed by applying a composition including a precursor of polyimide (including no photosensitive group) onto the sacrificial layer AL01 and curing the composition. The curing temperature is preferably in a range from 350 °C to 450 °C. While the thermosetting polyimide composition can be cured at a temperature of 500 °C or higher, by the temperature being 450 °C or higher, hydrogen released from the hydrogenated amorphous silicon layer formed as the sacrificial layer AL01 becomes significant, which may make it impossible to perform separation successfully in a separation step. Therefore, it is preferable to perform curing in the above temperature range. As described above, the first resin layer D10 is formed of a material having a higher Young's modulus than that of the intermediate resin layer D20 (the first intermediate resin layer D21 and the second intermediate resin layer D22) to be formed in a later step.

A silicon nitride layer as the first inorganic insulating layer D12 is formed on the first resin layer D10. The silicon nitride layer is formed by a vapor deposition method (plasma CVD method) using silane (SiH₄), ammonia (NH₃), and nitrogen (N₂). Further, the silicon nitride layer may be formed by a sputtering method.

FIG. 3B shows a step of forming first via holes TH11 and TH12 in the first resin layer D10 and the first inorganic insulating layer D12, and further forming a seed layer 120. When the first resin layer D10 is formed of a non-photosensitive resin composition, the first via holes TH11 and TH12 are formed by etching. Specifically, a resist mask is formed on the first inorganic insulating layer D12 by photolithography, and etching of the first inorganic insulating layer D12 is performed. In a case where the first inorganic insulating layer D12 is formed of a silicon nitride layer, dry etching can be performed using a fluorine-based etching gas. After that, etching of the first resin layer D10 is performed using the first inorganic insulating layer D12 as a hard mask. In a case where the first resin layer D10 is formed of polyimide, dry etching can be performed using a mixed gas of a fluorine-based gas such as CF₄, SF₆, or NF₃ and oxygen (O₂), or using only oxygen (O₂) gas as an etching gas.

After the first via holes TH11 and TH12 are formed, a seed layer 120 is formed over the entire surface of the glass substrate 150. The seed layer 120 is formed by forming a metal film such as copper (Cu) by a sputtering method. The seed layer 120 is formed with a thickness of about 10 nm to 100 nm.

FIG. 3C shows a step of forming a resist mask 130 on the seed layer 120 and forming first conductive vias V11 and V12. The first conductive vias V11 and V12 are formed by an electroplating method. For example, copper (Cu) is grown as the first conductive vias V11 and V12 by an electroplating method. Through electroplating, the copper (Cu) grows on a surface of the seed layer 120 exposed from the resist mask 130, fills the first via holes TH11 and TH12, and is further grown to have a thickness of 4 μm to 6 μm on the first resin layer D10.

FIG. 3D shows a step in which the resist mask 130 is removed after the electroplating process is completed, and the remaining seed layer 120 is etched to form the first conductive vias V11 and V12. Since the seed layer 120 remains on the entire surface of the glass substrate 150 after performing the electroplating, etching for removing the seed layer 120 is performed. Since the seed layer 120 is sufficiently thinner than the first conductive vias V11 and V12, the remaining seed layer 120 can be removed while leaving the first conductive vias V11 and V12 by etching the entire surface of the glass substrate 150.

FIG. 3E shows a state in which the first intermediate resin layer D21 is formed as an upper layer of the first conductive vias V11 and V12, a seed layer 122 and a resist mask 132 are further formed, and the second conductive vias V21 and V22 are formed. The first intermediate resin layer D21 is formed of a photosensitive resin composition with a thickness of 5 μm to 10 μm, for example, 7 μm. By performing exposure, development, and curing of the first intermediate resin layer D21, the second via holes TH21 and TH22 are formed. Since formation of the seed layer 122, the resist mask 132, and the second conductive vias V21 and V22 is similar to that in the previous step, a detailed description thereof is omitted.

FIG. 3F shows a step of forming the second intermediate resin layer D22 as an upper layer of the second conductive vias V21 and V22, forming the third conductive via V31 by electroplating through similar processes, and forming the second resin layer BSR. The second resin layer BSR is formed using a thermosetting resin material. The second resin layer BSR is formed by attaching a film called a prepreg (a prepreg containing no glass fiber) formed of the thermosetting epoxy resin material onto the second intermediate resin layer D22 and curing the film through heat treatment at a temperature of 150 °C to 250 °C.

The second resin layer BSR formed of such a material has a thickness of 30 μm to 40 μm and has a Young's modulus of about 7 GPa to 13 GPa. That is, the second resin layer BSR has a higher Young's modulus than that of the intermediate resin layer D20 (the first intermediate resin layer D21 and the second intermediate resin layer D22). Since the second resin layer BSR has a high Young's modulus along with the first resin layer D10, rigidity of a surface region of the multilayer wiring substrate 100 can be ensured, flatness when viewed as a whole is excellent, and flatness when viewed microscopically (when viewed in terms of a size of components to be mounted) can also be increased.

A first opening OP1 that exposes the third conductive via V31 is provided in the second resin layer BSR. The first opening OP1 is formed by, for example, performing laser processing.

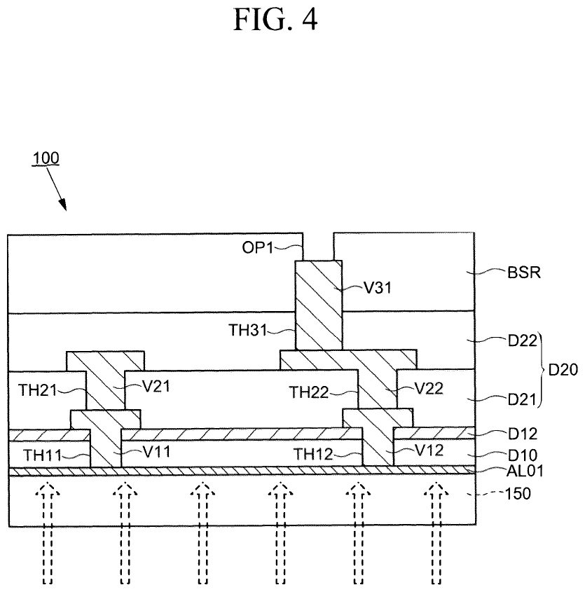

Through the steps described above, the multilayer wiring substrate 100 is formed on the glass substrate 150. After the multilayer wiring substrate 100 is formed on the glass substrate 150, a step of separating the multilayer wiring substrate 100 from the glass substrate 150 is performed. FIG. 4 shows a step of separating the multilayer wiring substrate 100 from the glass substrate 150. The separation step is performed by irradiating laser light from the glass substrate side 150. Upon irradiation with the laser light, the sacrificial layer AL01 is instantaneously heated to 500 °C or higher. In a case where the sacrificial layer AL01 is formed of a hydrogenated amorphous silicon film, upon irradiation with the laser light, hydrogen in the film is explosively released. By this hydrogen release, adhesion at an interface between the sacrificial layer AL01 and the first resin layer D10 is weakened. As a result, the multilayer wiring substrate 100 can be separated from the glass substrate 150. Such a separation method is also called a laser ablation method. In a case where polyimide is used for the first resin layer D10, by this laser ablation occurring at an interface between the glass substrate and the polyimide, separation can be performed at the interface, therefore, the sacrificial layer AL01 might not be required depending on a pattern.

Further, in a case where the sacrificial layer AL01 is formed, as described above, by applying the polyimide varnish including the soluble polyimide resin, the thermosetting cross-linking agent, and the solvent, and performing heat treatment at a temperature lower than the cross-linking start temperature of the cross-linking agent, by heating the sacrificial layer AL01 so as to promote a cross-linking reaction of the cross-linking agent, adhesion is reduced, and by applying an external force to one end, separation from the glass substrate 150 can be performed. Such a separation method is also called a mechanical separation method.

When the first resin layer D10 is formed of a thermosetting polyimide material, ablation occurs by irradiation of laser light, and adhesion to the glass substrate 150 can be weakened. On the other hand, since the first conductive vias V11 and V12 are formed by electroplating, the first conductive vias V11 and V12 have relatively strong adhesion to an underlying surface. However, by providing the sacrificial layer AL01 for separation on the glass substrate, the multilayer wiring substrate 100 can be separated without damaging the first conductive vias V11 and V12.

When the multilayer wiring substrate 100 is separated from the glass substrate 150, the multilayer wiring substrate 100 as shown in FIG. 1 can be obtained. The multilayer wiring substrate 100 is further provided with first bumps BP11 and BP12 and a second bump BP21 as shown in FIG. 2, and semiconductor integrated circuits (or circuit boards) arranged on a side of the first resin layer D10 and a side of the second resin layer BSR can be connected.

Since the first resin layer D10 and the second resin layer BSR form the outermost layers having high Young's moduli, the multilayer wiring substrate 100 according to this embodiment has high flatness. That is, in the multilayer wiring substrate 100, warping when viewed as a whole is prevented, and further, warping (microscopic warping) when viewed at a level of components to be mounted is reduced. Since the multilayer wiring substrate 100 has such high flatness, mounting accuracy can be increased, and occurrence of electrical connection failures can be prevented.

### Second Embodiment

This embodiment shows an aspect in which a configuration on the glass substrate side 150 in a manufacturing process is different from that of the multilayer wiring substrate shown in the First Embodiment. In the following description, parts different from those of the First Embodiment will be mainly described, and description of overlapping parts will be omitted.

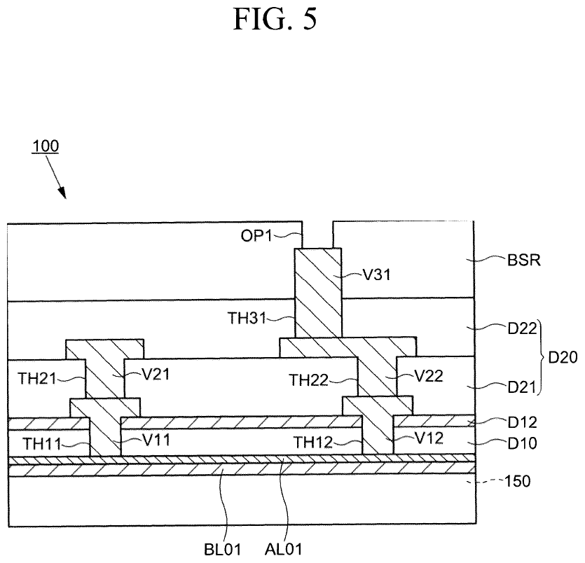

FIG. 5 is a cross-sectional view illustrating a configuration in a step where the multilayer wiring substrate 100 is formed on the glass substrate 150. As shown in FIG. 5, a base insulating layer BL01 is provided on a surface of the glass substrate 150.

As described in the First Embodiment, the glass substrate 150 has the first resin layer D10, the intermediate resin layer D20, and the second resin layer BSR stacked thereon, and further has a plating layer forming conductive vias and wiring formed between the respective resin layers. Such a plurality of layers stacked in this manner may cause the glass substrate 150 to warp due to an influence of internal stress (residual stress) of each layer. In particular, the first resin layer D10 formed of a thermosetting resin composition has a high tensile stress.

Accordingly, the base insulating layer BL01 having compressive stress provided on the glass substrate 150 prevents warping of the glass substrate 150 in the manufacturing process. That is, the base insulating layer BL01 having compressive stress provided on the glass substrate 150 offsets stresses and suppresses warping of the glass substrate 150 even if a layer such as the first resin layer D10 having tensile stress is formed on an upper-layer side thereof.

The base insulating layer BL01 preferably includes an insulating film formed of an inorganic material, and preferably includes a silicon nitride layer, an aluminum oxide layer, an aluminum nitride layer, or the like to have compressive stress. For example, the base insulating layer BL01 using a silicon nitride layer having compressive stress of about 300 MPa suppresses warping of the glass substrate 150 caused by forming a resin layer. While internal stress of the silicon nitride layer depends on film formation conditions, the silicon nitride layer having a thickness of 300 nm or more increases the internal stress.

Further, the base insulating layer BL01 may have a structure in which a silicon oxide layer and a silicon nitride layer are stacked. The base insulating layer BL01 having the silicon oxide layer and the silicon nitride layer stacked in this order from the glass substrate 150 side improves adhesion and prevents separation.

The sacrificial layer AL01 is provided on the base insulating layer BL01. The silicon nitride layer used as the base insulating layer BL01 is sufficiently transparent to light in a range from a visible region to an infrared region, and thus does not exert an influence even when the multilayer wiring substrate 100 is separated by irradiating the sacrificial layer AL01 with laser light. The base insulating layer BL01 remaining on the glass substrate 150 after the separation allows the glass substrate 150 to be reused.

As shown in this embodiment, the base insulating layer BL01 provided on the glass substrate 150 prevents warping of the glass substrate 150 in the manufacturing process and prevents unintended separation of the resin layer. The configuration of the multilayer wiring substrate 100 according to this embodiment is similar to that of the First Embodiment except for including the base insulating layer BL01, and provides similar effects.

### Third Embodiment

This embodiment shows an aspect in which a configuration of an intermediate resin layer differs from that of the multilayer wiring substrate shown in the First Embodiment. In the following description, parts different from those of the First Embodiment will be mainly described, and description of overlapping parts will be omitted.

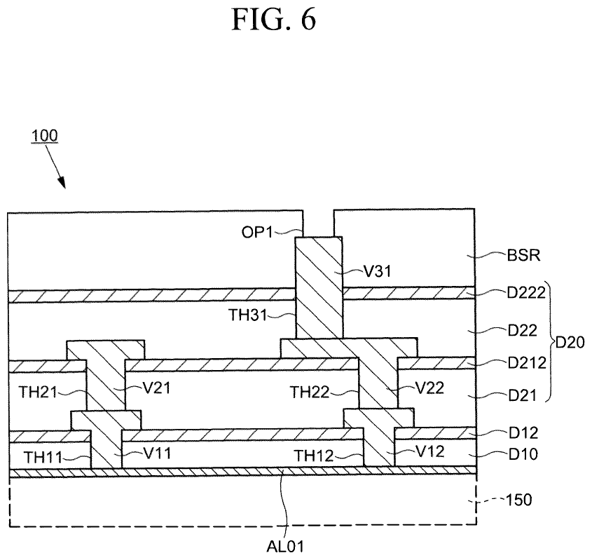

In the First Embodiment, the intermediate resin layer D20 was formed of a photosensitive resin composition, but in this embodiment, the intermediate resin layer D20 is formed of a non-photosensitive resin composition. FIG. 6 shows an example in which the first intermediate resin layer D21 and the second intermediate resin layer D22 are formed of a non-photosensitive resin material. The first intermediate resin layer D21 and the second intermediate resin layer D22 are formed of a non-photosensitive resin composition similar to that of the first resin layer D10. The first intermediate resin layer D21 and the second intermediate resin layer D22 formed by curing the non-photosensitive resin composition have high Young's moduli similarly to the first resin layer D10.

A second inorganic insulating layer D212 is provided on the first intermediate resin layer D21, and a third inorganic insulating layer D222 is provided on the second intermediate resin layer D22. The second inorganic insulating layer D212 and the third inorganic insulating layer D222 are layers having compressive stress similar to the first inorganic insulating layer D12, and are preferably formed of a silicon nitride layer.

The first intermediate resin layer D21 and the second intermediate resin layer D22 formed of a non-photosensitive resin composition have tensile stress, similar to the first resin layer. In contrast, the second inorganic insulating layer D212 and the third inorganic insulating layer D222 having compressive stress offset the tensile stress and prevent warping of the multilayer wiring substrate 100. Etching forms the second via holes TH21 and TH22 in the first intermediate resin layer D21 and a third via hole TH31 in the second intermediate resin layer D22. At this time, the second inorganic insulating layer D212 and the third inorganic insulating layer D222 serve as a hard mask for the etching. In a case where the first intermediate resin layer D21 and the second intermediate resin layer D22 are formed of polyimide, a mixed gas of a fluorine-based gas such as CF₄, SF₆, or NF₃ and oxygen (O₂), or only oxygen (O₂) gas is used for dry etching.

The configuration of the multilayer wiring substrate 100 according to this embodiment increases the Young's moduli of the respective resin layers and offsets the internal stress (residual stress) of each resin layer, thereby providing the multilayer wiring substrate 100 that has excellent flatness and is capable of adapting to high-density mounting. The configuration of the multilayer wiring substrate 100 according to this embodiment is similar to that of the First Embodiment except for a difference in the configuration of the intermediate resin layer D20, and provides similar effects.

Note that the configuration of this embodiment is capable of being appropriately combined with the configuration of the base insulating layer BL01 shown in the Second Embodiment.

### Fourth Embodiment

This embodiment shows a configuration of a multilayer wiring substrate in which a diameter of via holes is large. In the following description, parts different from those of the First Embodiment will be mainly described, and description of overlapping parts will be omitted.

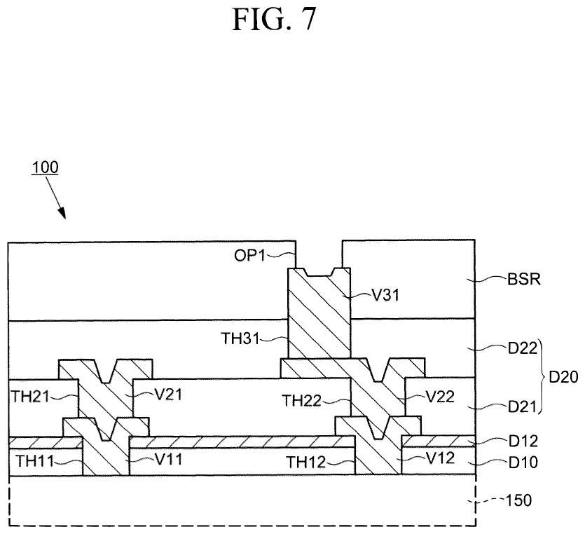

FIG. 7 schematically shows a cross-sectional structure of the multilayer wiring substrate 100 in a case where a diameter of a via hole is relatively large (for example, in a case where the diameter is 20 μm or more). In a case where the diameter of the via hole formed in each resin layer is large, a conductive via formed by electroplating might not sufficiently fill the via hole. In such a case, the conductive via has a concave shape in a region corresponding to a central portion of the via hole. In other words, the conductive via has a shape along a concave shape formed by the via hole.

The intermediate resin layer D20 is formed by applying a photosensitive resin composition and performing exposure. The intermediate resin layer D20 fills the unevenness of the base by utilizing fluidity during application of the photosensitive resin composition, thereby forming a flat surface. In this case, the top surface of the conductive via having a concave shape increases the film thickness of the intermediate resin layer D20 in a region overlapping this concave shape.

A positive type of photosensitive resin composition forming the intermediate resin layer D20 requires exposure of a portion where a via hole is to be formed. For example, exposure of a portion where the film thickness of the resin layer has increased might lead to insufficient exposure and cause residues to remain after development. On the other hand, an attempt to sufficiently expose the portion where the film thickness of the intermediate resin layer D20 has increased causes other portions (portions where the film thickness has not increased) to be overexposed, which is undesirable.

The multilayer wiring substrate 100 according to this embodiment includes the intermediate resin layer D20 formed of a negative-type photosensitive resin composition to resolve such a problem. Using the negative-type resin composition, a region of a via hole becomes an unexposed region, therefore, even if the film thickness increases, insufficient exposure does not occur. As a result, because the cross-sectional shape of the via hole is made substantially vertical, separation in the vicinity of the conductive via can also be prevented.

The configuration of the multilayer wiring substrate 100 according to this embodiment is similar to that of the First Embodiment except for the intermediate resin layer D20 being formed of a negative-type photosensitive resin composition, and provides similar effects.

Note that the configuration of this embodiment is appropriately combinable with the configuration of the base insulating layer BL01 shown in the Second Embodiment.

### Fifth Embodiment

This embodiment shows an aspect in which a configuration of the first resin layer differs from that of the First Embodiment. The following description focuses on parts different from those of the First Embodiment and omits description of overlapping parts.

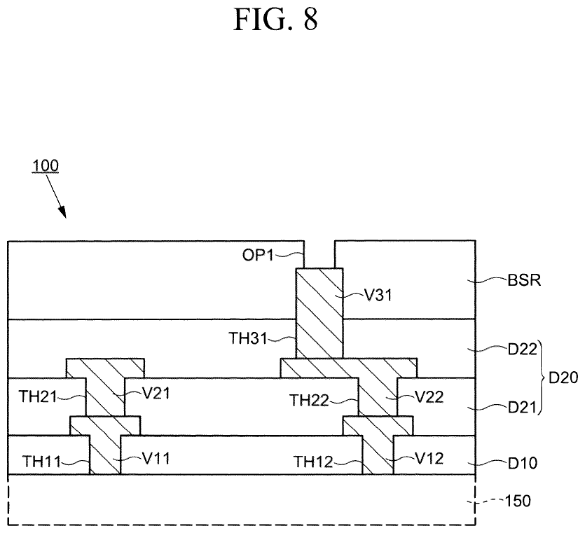

FIG. 8 shows a cross-sectional view of a configuration of the multilayer wiring substrate 100 according to this embodiment. The multilayer wiring substrate 100 according to this embodiment differs from the multilayer wiring substrate shown in the First Embodiment in that the first resin layer D10 lacks the first inorganic insulating layer thereon. The first inorganic insulating layer is removed after the formation of the first via holes TH11 and TH12.

The configuration shown in FIG. 8 improves the toughness of the multilayer wiring substrate 100. Specifically, the configuration enhances toughness against bending even in a case where the multilayer wiring substrate 100 is curved. Furthermore, the multilayer wiring substrate 100 prevents cracks and improves reliability even when thermal stress, such as a temperature rise and a subsequent temperature drop during energization, acts on the multilayer wiring substrate 100.

Further, in the cross-sectional view of FIG. 8, the first resin layer D10 having a Young's modulus higher than that of the intermediate resin layer D20 allows the first resin layer D10 to include a photosensitive resin. For example, a photosensitive polyimide material applied to the first resin layer D10 and a photosensitive phenol resin applied to the intermediate resin layer D20 set the Young's modulus of the first resin layer D10 relatively higher than that of the intermediate resin layer D20. The photolithography process for patterning the first resin layer D10 using the photosensitive resin reduces dry etching damage during processing, therefore, the second resin layer BSR maintaining a high Young's modulus ensures the flatness of the multilayer wiring substrate 100 after separation even if the material of the first resin layer D10 has a low inherent Young's modulus. A negative-type or positive-type photosensitivity is applicable to the polyimide material.

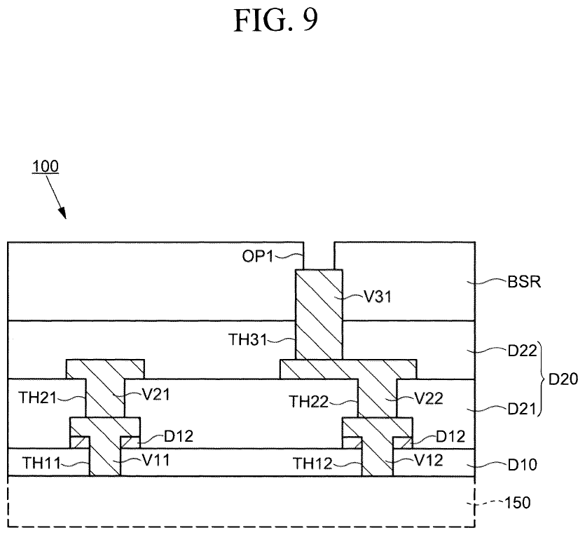

FIG. 9 shows a configuration of the multilayer wiring substrate 100 in which the first inorganic insulating layer is similarly removed from above the first resin layer D10. The configuration shown in FIG. 9 shows the first inorganic insulating layer D12 removed after the formation of first conductive vias V11 and V12. This configuration lacks the first inorganic insulating layer in most regions, while the first inorganic insulating layer D12 remains under the first conductive via V11.

The configuration shown in FIG. 9 increases the toughness of the multilayer wiring substrate 100. Simultaneously, the first inorganic insulating layer D12 (for example, silicon nitride) interposed between the first conductive vias V11 and V12 formed of a metal (for example, copper (Cu)) and the first resin layer D10 formed of a resin material (for example, polyimide) improves adhesion of the first conductive vias V11 and V12 to the first resin layer D10 and prevents separation.

The configuration of the multilayer wiring substrate 100 according to this embodiment is similar to that of the First Embodiment except for the first inorganic insulating layer D12 being removed, and provides similar effects.

Note that the configuration of this embodiment is appropriately combinable with the configurations shown in the Second to Fourth Embodiments.

### Sixth Embodiment

This embodiment shows an example in which a configuration of a conductive via provided in the first resin layer differs from that of the multilayer wiring substrate shown in the First Embodiment. The following description focuses on parts different from those of the First Embodiment and omits description of overlapping parts.

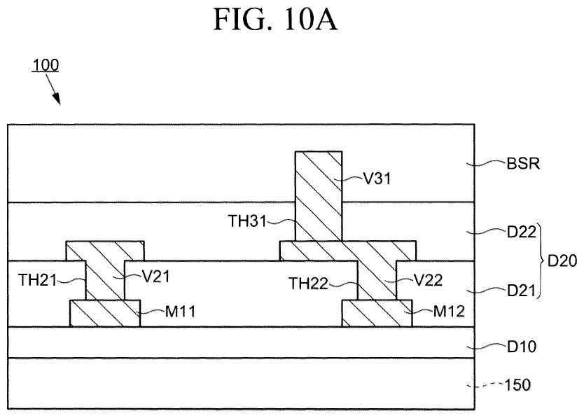

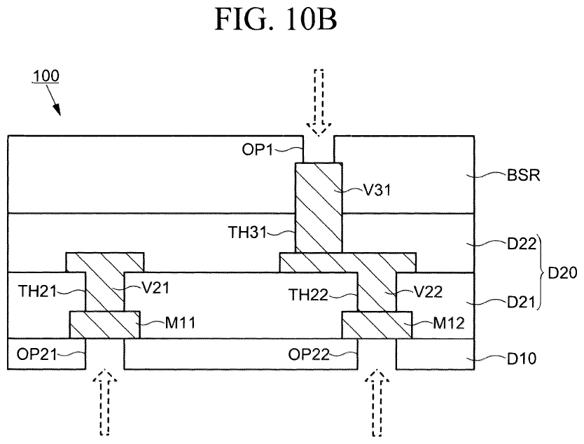

FIG. 10A shows a stage at which the multilayer wiring substrate 100 according to this embodiment is formed on the glass substrate 150. The multilayer wiring substrate 100 according to this embodiment has a structure in which the first resin layer D10 lacks a conductive via and wiring M11 and M12 are provided on the first resin layer D10. Electroplating forms the wiring M11 and M12 similar to the first conductive via. At this stage, the first resin layer D10 lacks a through hole for forming a via hole.

FIG. 10B shows a state in which the multilayer wiring substrate 100 is separated from the glass substrate 150. As described in the First Embodiment, a laser ablation method or a mechanical peeling method separates the multilayer wiring substrate 100. Thereafter, laser light irradiation from the second resin layer BSR side forms a first opening OP1, and laser light irradiation from the first resin layer D10 side forms second openings OP21 and OP22 exposing the wiring M11 and M12.

This embodiment maintains the first resin layer D10 in a solid state (a state without via holes) until the formation of the second resin layer BSR, and finally forms the second openings OP21 and OP22. The higher rigidity of the first resin layer D10 during such a process improves the dimensional accuracy of the multilayer wiring substrate 100.

The configuration of the multilayer wiring substrate 100 according to this embodiment is similar to that of the First Embodiment except for the configuration relating to the first conductive via being different, and provides similar effects.

The configuration of this embodiment is appropriately combinable with the configurations shown in the Second to Fifth Embodiments.

The various configurations of the multilayer wiring substrate exemplified as the embodiments of the present invention are appropriately combinable as long as they are not mutually contradictory. Furthermore, based on the multilayer wiring substrate disclosed in the present specification and drawings, the scope of the present invention also encompasses additions, deletions, or design changes of components, or additions, omissions, or condition changes of processes appropriately made by those skilled in the art, as long as they possess the gist of the present invention.

The present invention naturally provides other effects that are apparent from the description of the present specification or readily predictable by those skilled in the art, even if the effects differ from those brought about by the aspects of the embodiments disclosed in the present specification.

What is claimed is:

1. A multilayer wiring substrate, comprising:
a first resin layer;
a second resin layer overlapping the first resin layer in a plan view;
at least one intermediate resin layer between the first resin layer and the second resin layer; and
at least one conductive via provided in the at least one intermediate resin layer,
wherein the first resin layer forms an outermost layer on a first surface side,
wherein the second resin layer forms an outermost layer on a second surface side opposite to the first surface side, and
wherein a Young's modulus of the first resin layer and a Young's modulus of the second resin layer are higher than a Young's modulus of the at least one intermediate resin layer.

2. The multilayer wiring substrate according to claim 1, wherein the Young's modulus of the first resin layer and the Young's modulus of the second resin layer are each 5 GPa or more.

3. The multilayer wiring substrate according to claim 2, wherein the first resin layer and the second resin layer are formed of resin materials that do not include a photosensitive group.

4. The multilayer wiring substrate according to claim 1, further comprising a first bump on a side of the first resin layer and a second bump on a side of the second resin layer,
wherein the at least one conductive via includes a first conductive via exposed from the first resin layer on the first surface side, and a second conductive via exposed from the second resin layer on the second surface side, and
wherein the first bump is electrically connected to the first conductive via, and the second bump is electrically connected to the second conductive via.

5. The multilayer wiring substrate according to claim 1, further comprising a first inorganic insulating layer,
wherein the at least one intermediate resin layer includes a first intermediate resin layer adjacent to the first resin layer, and
wherein the first inorganic insulating layer is provided between the first resin layer and the first intermediate resin layer.

6. The multilayer wiring substrate according to claim 5, wherein the first resin layer has tensile stress, and the first inorganic insulating layer has compressive stress.

7. The multilayer wiring substrate according to claim 1, further comprising a first inorganic insulating layer, a second inorganic insulating layer, and a third inorganic insulating layer,
wherein the at least one intermediate resin layer includes a first intermediate resin layer adjacent to the first resin layer and a second intermediate resin layer adjacent to the second resin layer,
wherein the first inorganic insulating layer is provided between the first resin layer and the first intermediate resin layer,
wherein the second inorganic insulating layer is provided between the first intermediate resin layer and the second intermediate resin layer, and
wherein the third inorganic insulating layer is provided between the second intermediate resin layer and the second resin layer.

8. The multilayer wiring substrate according to claim 7, wherein the first resin layer, the first intermediate resin layer, and the second intermediate resin layer have tensile stress, and the first inorganic insulating layer, the second inorganic insulating layer, and the third inorganic insulating layer have compressive stress.

9. The multilayer wiring substrate according to claim 1, wherein the second resin layer is thicker than the first resin layer.

10. A method for manufacturing a multilayer wiring substrate having a first resin layer, a second resin layer overlapping the first resin layer in a plan view, at least one intermediate resin layer between the first resin layer and the second resin layer, and at least one conductive via provided in the at least one intermediate resin layer,
the method comprising:
forming the first resin layer by applying a non-photosensitive resin composition onto a glass substrate and curing the non-photosensitive resin composition;
forming the second resin layer from a thermosetting organic-inorganic composite material; and
forming the at least one intermediate resin layer from a photosensitive resin material.

11. The method according to claim 10, wherein the first resin layer and the second resin layer are formed of materials having a Young's modulus higher than that of the at least one intermediate resin layer.

12. The method according to claim 10, further comprising forming a first inorganic insulating layer having compressive stress on a surface of the first resin layer.

13. The method according to claim 12, further comprising, before forming the first resin layer, forming an underlying inorganic insulating layer having compressive stress on the glass substrate.

14. The method according to claim 10, wherein the second resin layer is formed from a coating-type or film-like organic-inorganic composite material.

15. The method according to claim 10, wherein the first resin layer is formed by applying a non-photosensitive polyimide composition and curing the non-photosensitive polyimide composition.

16. The method according to claim 10, further comprising:
forming a sacrificial layer on the glass substrate;
forming the first resin layer on the sacrificial layer; and
after forming the second resin layer, irradiating the sacrificial layer with laser light to separate the first resin layer, the at least one intermediate resin layer, and the second resin layer from the glass substrate.

17. The method according to claim 16, wherein the sacrificial layer is formed of a silicon semiconductor containing hydrogen, and a curing temperature of the first resin layer is 450 °C or lower.

18. A multilayer wiring substrate comprising:
a first resin layer formed of a non-photosensitive material or a photosensitive resin material;
a second resin layer overlapping the first resin layer in a plan view and formed of a thermosetting organic-inorganic composite material;
at least one intermediate resin layer formed of a photosensitive material between the first resin layer and the second resin layer; and
at least one conductive via provided in the at least one intermediate resin layer,
wherein the first resin layer forms an outermost layer on a first surface side, and
wherein the second resin layer forms an outermost layer on a second surface side opposite to the first surface side.

19. The multilayer wiring substrate according to claim 18, wherein the first resin layer is formed of non-photosensitive polyimide, and the second resin layer is formed of a thermosetting epoxy resin material including an epoxy resin, an active ester compound including a naphthalene structure, and an inorganic filler.

20. The multilayer wiring substrate according to claim 18, wherein a Young's modulus of the first resin layer and a Young's modulus of the second resin layer are higher than a Young's modulus of the intermediate resin layer.
